(19) United States
(12) Patent Application Publication
(10) Pub. No.: US 2026/0201540 A1
(43) Pub. Date: Jul. 16, 2026

(54) SOURCE ARRANGEMENT AND THERMAL LASER EPITAXY SYSTEM

(71) Applicant: Max-Planck-Gesellschaft zur Förderung der Wissenschaften e.V., München (DE)

(72) Inventor: Wolfgang Braun, Bietigheim-Bissingen (DE)

(21) Appl. No.: 19/132,428

(22) PCT Filed: Dec. 23, 2022
(86) PCT No.: PCT/EP2022/087723

§ 371 Date: May 23, 2025

(51) Int. Cl. C23C 14/28

(52) U.S. Cl. CPC C23C 14/28

(57) ABSTRACT

The present invention relates to a source arrangement for a thermal laser epi-taxy (TLE) system. The system comprises a holding device with a movable holding structure with one or more holding spaces for the arrangement of one or more source elements providing a source material to be evaporated and/or sublimated by a laser beam of the TLE system for a coating of a sub-strate of the TLE system.

The invention relates to a source arrangement for a thermal laser epitaxy (TLE) system, comprising a holding device with a movable holding structure with one or more holding spaces for the arrangement of one or more source elements providing a source material to be evaporated and/or sublimated by a laser beam of the TLE system for a coating of a substrate of the TLE system. Further, the invention relates to a thermal laser epitaxy (TLE) system for coating a surface of a substrate with a layer comprising one or more source materials, comprising a reaction chamber enclosing a reaction volume sealable with respect to the ambient atmosphere, a gas system for providing an adjustable reaction atmosphere within the reaction volume, an arrangement means for arranging a substrate within the reaction volume, a substrate heating means for heating the substrate, a laser system for providing one or more laser beams for evaporating and/or sublimating the one or more source materials, and a source arrangement for providing the one or more source materials within the reaction chamber.

In thermal laser epitaxy systems, a laser beam impinges on a source element providing a source material and causes it to evaporate or sublimate. The laser beam is directed at an angle to the source such that the evaporation flux, which generally is normal to a surface of the source element, can reach a substrate to be coated without interference with laser beam forming and guiding components. Small movements of both the laser beam and the source are possible, for instance for changing a size, position and/or a shape of a projection of the laser beam on the source element, and/or for compensating material loss due to the evaporation and/or sublimation process. Often, a focal point of the laser beam is kept stationary and away from the source element for arranging an aperture to reduce coating of upstream optical components.

In many practical applications, however, one would like to change the working distance of the source elements with respect to the substrate to be coated by significant amounts, e.g. to change deposition gradients along the substrate, or to place sources with strongly different operating temperatures at larger distances to each other. Also, one may want to use the same laser either with the same source at different working distances to increase the range of beam projections on the source, or use different sources with the same laser. The known source arrangements of the state of the art cannot meet these requirements.

In view of the above, it is an object of the present invention to provide an improved source arrangement, and an improved thermal laser epitaxy system which do not have the drawbacks of the state of the art. In particular, it is an object of the present invention to provide an improved source arrangement, and an improved thermal laser epitaxy system, which allow using the same laser beam for evaporation and/or sublimation of source material provided by a source element at different working distances to the substrate to be coated, in particular with the same source element and/or different source elements.

This object is satisfied by the respective independent patent claims. In particular, this object is satisfied by a source arrangement according to claim 1, and by a thermal laser epitaxy system according to claim 19. The dependent claims describe preferred embodiments of the invention. Details and advantages described with respect to the source arrangement according to the first aspect of the invention also refer to the thermal laser epitaxy system according to the second aspect of the invention and vice versa, if of technical sense.

According to the first aspect of the invention, the object is satisfied by a source arrangement for a thermal laser epitaxy (TLE) system, comprising a holding device with a movable holding structure with one or more holding spaces for the arrangement of one or more source elements providing a source material to be evaporated and/or sublimated by a laser beam of the TLE system for a coating of a substrate of the TLE system. The source arrangement according to the present invention is characterized in that it further comprises an actuator mechanically coupled to the holding structure, whereby the actuator is constructed to move the holding structure between two or more holding positions, wherein in a first holding position of the two or more holding positions one of the one or more source elements arranged in the respective holding spaces is positional along the laser beam at a first interaction position, and wherein in a second holding position of the two or more holding positions one of the one or more source elements arranged in the respective holding spaces is positional along the laser beam at a second interaction position different to the first interaction position.

The source arrangement according to the present invention is constructed to be used in a TLE system. The purpose of the source arrangement within the TLE system, in particular in a reaction chamber of the TLE system, is providing one or more source elements which provide source materials to be evaporated and/or sublimated by the one or more laser beams of the TLE system. The evaporated and/or sublimated source materials are deposited onto a substrate for forming an epitaxial layer on said substrate.

For the provision of the one or more source elements, the source arrangement according to the present invention comprises a holding structure with one or more holding spaces for the arrangement of the respective source elements. The holding spaces are constructed for receiving the respective source elements, for instance by form-fittingly embracing said source elements and/or by providing accordingly constructed fixing means such as screws or clamps for fixing said source elements at the respective holding space. Typical sizes for source elements for a TLE system, in particular a TLE system used for research purposes, are 8 mm in height and between 2 mm and 12.7 mm in diameter, hence the respective holding spaces for such source elements comprise accordingly selected dimensions. Also, the usage of adaptors for fittingly reducing the size of the available space of the holding spaces to the size of the respective source elements is possible. Alternatively, also holding structures with source elements already pre-fixed into the respective holding spaces can be used.

Said holding structure is movable and further mechanically coupled to an actuator, wherein the actuator serves to move the holding structure between at least two or more different holding positions. The actuator can comprise for instance an electric motor and additional gear means and/or mechanical transmission elements for moving the holding structure.

In particular, the holding structure, driven by the actuator, can at least be positioned in a first holding position and in a second holding position, wherein the first and second holding positions are different. In other words, the actuator moves the complete holding structure between the two different holding positions, namely the first holding position and the second holding position. Different in the sense of the present invention especially means that the difference between the first and second holding position is not marginal and clearly distinguishable, preferably the holding structure is moved between the two holding positions by 5 mm or more, in particular 10 mm or more, preferably 25 mm or more.

The relative positions of the two or more holding spaces at the holding structure are fixed. In other words, when the holding structure is moved by the actuator between its two or more holding positions, automatically also all holding spaces move accordingly.

According to the present invention, the first holding position and the second holding position of the holding structure are not only different, but additionally linked by their respective relative positions with respect to the laser beam of the TLE system when implemented in the respective TLE system. In particular, the two different holding positions of the holding structure are selected in a way that not only one of the holding spaces is arranged such that a source element arranged in the respective holding space is arranged at an interaction position of the laser beam, but also that the first interaction position linked to the first holding position of the holding structure is different to the second interaction position linked to the second holding position of the holding structure. Again, different in the sense of the present invention especially means that the difference between the first and second interaction positions is not marginal and clearly distinguishable, preferably the distance between the two interaction positions along the laser beam is 5 mm or more, in particular 10 mm or more, preferably 25 mm or more. An interaction position in the sense of the present invention is a position along the laser beam, at which a source element arranged in a holding space is illuminated by the laser beam, presumed that the holding structure and hence the holding space is in a suitably selected position.

In summary, the source arrangement according to the present invention allows arranging source elements at two or more different interaction positions along the laser beam of a TLE system. As the laser beam of a TLE system, which is used for evaporating and/or sublimating source material, is aligned within the TLE system angled to the surface of the substrate, as a parallel alignment of the laser beam with respect to the surface of the substrate would be an inefficient alignment for a deposition of said evaporated and/or sublimated source material onto the surface of the substrate, the two or more interaction positions simultaneously comprise different distances to the surface of the substrate. In other words, by using the source arrangement according to the present invention in a TLE system, the same laser beam can be used for evaporation and/or sublimation of source material provided by a source element at different working distances to the surface of the substrate.

Further, the source arrangement according to the present invention can comprise that in a mounted state of the source arrangement, a substrate distance of the second holding position to the substrate is larger than a substrate distance of the first holding position to the substrate. In this specific embodiment, in a mounted state of the source arrangement according to the present invention, the holding structure in its second holding position is positioned within the TLE system farther away from the substrate than the holding structure in its first holding position. Consequently, also the holding spaces are arranged more distant from the substrate, when the holding structure is arranged in its second holding position. By specifying the second holding position as the position more distant from the substrate, planning a coating process of the substrate in the TLE system can be made possible or at least easier, in particular with respect to the different substrate distances of the source elements to the substrate provided by the different holding positions of the holding structure.

Additionally, or alternatively, the source arrangement according to the present invention can also be characterized in that the second interaction position is downstream on the laser beam with respect to the first interaction position. As mentioned above, the laser beam of a TLE system is angled with respect to the surface of the substrate. Hence, also by defining the second interaction position downstream on the laser beam with respect to the first interaction position, two different distances of said interaction positions to the substrate can be provided. Hence, evaporation and/or sublimation of source material provided by a source element at different working distances to the substrate to be coated can be provided easily.

According to another embodiment of the source arrangement according to the present invention, the actuator is constructed for linearly moving the holding structure and/or for rotating the holding structure. Preferably, the actuator is constructed for both, linearly moving and rotating, respectively, the holding structure. More preferably, an axis of the rotational movement of the holding structure provided by the actuator is parallel to the direction of the linear movement of the holding structure likewise provided by the actuator. Alternatively, or additionally, the direction of the linear movement can be aligned normal to the surface of the substrate. Linear and rotational movements are very simple movements which can easily be determined and controlled, in particular with respect to the respective providable distance of source elements arranged in the holding spaces to the surface of the substrate. Hence, by providing linear and rotational movements of the holding structure, a source arrangement according to the present invention, and especially also a TLE system with such a source arrangement, can be simplified.

According to a further enhanced embodiment of the source arrangement according to the present invention, the linear movement of the holding structure is parallel to a mean direction of the evaporated and/or sublimated source material of the respective source element when illuminated by the laser beam. The mean direction of the evaporated and/or sublimated source material is the most suitable direction in which the substrate to be coated should be arranged. In most of the cases, said mean direction is normal to a surface of the respective source element, and the substrate is arranged within the TLE system such that said mean direction is likewise normal also to the surface of the substrate. By aligning the linear movement parallel to said mean direction it can be ensured that in both holding positions, namely in the first holding position and in the second holding position, respectively, linked by said linear movement, the mean direction of the evaporated and/or sublimated source material stays the same. With an accordingly arranged substrate as described in this paragraph, a coating of the substrate with the optimum available flow of evaporated and/or sublimated source material can be provided.

Additionally, or alternatively, the source arrangement according to the present invention can be enhanced further by that an axis of the rotational movement of the holding structure is parallel to the mean direction of the evaporated and/or sublimated source material of the respective source element arranged in the respective holding space when illuminated by the laser beam. As mentioned above, the mean direction of the evaporated and/or sublimated source material is the most suitable direction in which the substrate to be coated should be arranged. By aligning the axis of the rotational movement parallel to said mean direction it can be ensured that in both holding positions, namely in the first holding position and in the second holding position, respectively, linked also by said rotational movement, the mean direction of the evaporated and/or sublimated source material stays the same. With an accordingly arranged substrate as described in this paragraph, a coating of the substrate with the optimum available flow of evaporated and/or sublimated source material can be provided.

Further, the source arrangement according to the present invention can be characterized in that a first holding space arrangeable at the first interaction position along the laser beam when the holding structure is in its first holding position is the same as a second holding space arrangeable at the second interaction position along the laser beam when the holding structure is in its second holding position. In other words, a source element arranged in said holding space will be illuminated by the laser beam in both holding positions of the holding structure, and the same source material will be evaporated and/or sublimated. As the flow of an evaporated and/or sublimated source material diminishes with increasing distance to the respective source element, coating a substrate with the same source material but with different flow intensities of the evaporated and/or sublimated source material can be provided.

Alternatively, or additionally, the source arrangement according to the present invention can also comprise that a first holding space arrangeable at the first interaction position along the laser beam when the holding structure is in its first holding position is different from a second holding space arrangeable at the second interaction position along the laser beam when the holding structure is in its second holding position. In other words, in the first and second holding positions of the holding structure, different holding spaces are arranged along the path of the laser beam. When in said different holding spaces source elements providing the same source material are arranged, the same advantages as described in the previous paragraph can be provided. However, when in the different holding spaces source elements providing different source materials are arranged, fast and easy switching between an evaporation and/or sublimation of said different source materials can be provided by simply moving the holding structure of the source arrangement between its holding positions. A layer structure of the coating of the substrate can thereby be provided easily.

According to a further enhanced embodiment of the source arrangement according to the present invention, the first holding space and the second holding space are arranged at the holding structure in a holding plane, wherein the holding plane is normal to the mean direction of the evaporated and/or sublimated source material of the respective source element arranged in the respective holding space when illuminated by the laser beam. For instance, the holding structure can be constructed similar to a wheel with spokes. By arranging the two holding spaces, preferably all holding spaces of the holding structure, in a plane normal to the mean direction of the evaporated and/or sublimated source material, the design of the holding structure and hence of the entire source arrangement can be kept especially simple.

In addition, the source arrangement according to the present invention can be enhanced further by that the linear movement of the holding structure provided by the actuator is parallel to the mean direction of the evaporated and/or sublimated source material of the respective source element arranged in the respective holding space when illuminated by the laser beam, and wherein a source distance between the first holding space and the second holding space within the holding plane and an interplanar distance of the holding plane with the first holding space in the first interaction position to the holding plane with the second holding space in the second interaction position are selected with respect to an incidence angle of the laser beam of the TLE system on a surface of the source element arrangeable in the first holding space and the second holding space, respectively. In this enhanced embodiment, the aforementioned holding structure with a holding plane, in which the holding spaces are arranged, is enhanced by that the source distance and the interplanar distance are selected such that they are accordingly selected with respect to the laser beam to be used for the evaporation and/or sublimation. In particular, the incidence angle, with which the laser beam will impinge onto the source elements arranged in the first and second holding spaces, respectively, will be identical. As the surfaces of said source elements are essentially parallel to the holding plane, said incidence angle of the laser beam is also the angle of the laser beam with the holding plane. By accordingly selecting both the source distance and the interplanar distance, respectively, with respect to the incidence angle of the laser beam, an arrangement of the first and second holding space, and hence of any source element arranged at said holding spaces, at the first and second intersection positions, respectively, of the laser beam can be ensured.

Further, the source arrangement can also be enhanced by that the source distance and the interplanar distance are selected such that the value of the interplanar distance divided by the value of the source distance is the tangent of the incidence angle. In other words, if the laser beam impinges on a source element arranged in a holding space when the holding structure in its first holding position, the laser beam will impinge on a source element arranged in the next holding space when the holding structure is in its second holding position.

The source distance, the interplanar distance and the beam path of the laser beam between the first interaction position and the second interaction position form an orthogonal triangle, as the interplanar distance is normal to the holding plane.

Hence, as the incidence angle is defined between the holding plane and the laser beam, selecting the source distance, the interplanar distance and the incidence angle such that the aforementioned relation is fulfilled ensures an arrangement of the first and second holding space, and hence again of any source element arranged at said holding spaces, at the first and second intersection positions, respectively, of the laser beam. Especially, for any pair of these variables, for instance source distance and incidence angle, the third variable, in the aforementioned example the interplanar distance, can easily be determined.

Further, the source arrangement according to the present invention can also be enhanced by that the source arrangement is constructed for usage in a TLE system with at least a first laser beam and a second laser beam and hence comprises at least two holding space pairs of a first holding space and a second holding space, wherein the respective source distance between the first holding space and the second holding space of each holding space pair is selected with respect to the incidence angle of the respective laser beam and a common interplanar distance. Analogous to the embodiment described above with a single laser beam, by accordingly selecting the source distance of each respective holding space pair with respect to the incidence angle of the respective laser beam and the shared interplanar distance, for each holding space pair, an arrangement of the respective first and second holding space, and hence of any source element arranged at said holding spaces, at the respective first and second intersection positions, respectively, of the respective laser beam can be ensured. This also holds true for more than two lasers and accordingly more than two holding space pairs. It is noted that already three holding spaces are sufficient for forming two holding space pairs, wherein one of the holding spaces is part of both holding space pairs.

In a first alternative enhancement of the source arrangement according to the present invention, the respective incidence angles of the laser beams and hence the respective source distances of the holding space pairs are different. By providing different incidence angles of the provided laser beams, different evaporation and/or sublimation characteristics of the evaporated and/or sublimated source materials of the respective source elements can be provided. By considering said different incidence angles by selecting the respective source distances of the respective holding spaces of the holding space pairs, this advantage can also be provided in TLE systems using the source arrangement according to the present invention.

According to a second enhancement of the source arrangement according to the present invention, the respective incidence angles of the laser beams and hence the respective source distances of the holding space pairs are equal. By using only the same incidence angle for all provided laser beams, for all evaporated and/or sublimated source materials a similar, preferably identical, evaporation and/or sublimation characteristics can be provided. By considering said uniform incidence angles and hence also selecting the respective source distances of the respective holding spaces of the holding space pairs identical, this advantage can also be provided in TLE systems using the source arrangement according to the present invention.

In a further enhanced embodiment of the source arrangement according to the present invention, the holding structure comprises three or more holding spaces, wherein the three or more holding spaces form a regular holding polygon. A regular polygon, and hence also a regular holding polygon, is a planar convex shape with a closed outline and equal side length. When a regular polygon is rotated by a certain polygon angle defined by 360° divided by the number of vertices of the polygon, the polygon merges back into itself. Hence, a holding structure in which the holding spaces form a regular holding polygon can be arranged within the source arrangement according to the present invention in different rotational orientations defined by the polygon angle without losing the relative orientation with respect to the laser beams. When the aforementioned rotational orientation is realized, the matching between holding spaces and laser beam in both, the first holding positions and the second holding positions, respectively, is preserved. Possible applications of the source arrangement according to the present invention in a TLE system can thereby be enhanced.

In addition, the source arrangement according to the present invention can be enhanced further by that a center of the holding polygon is arrangeable in the TLE system opposite to the substrate. An arrangement opposite to the substrate in the scope of the present invention especially is an arrangement of the center of the holding polygon of the source arrangement such that a normal to the holding polygon, and hence to the holding plane and the mean direction of evaporated and/or sublimated source material, respectively, is directed towards the surface of the substrate, preferably with an impingement angle of 90°. An especially good coverage of the whole surface of the substrate by the coating of evaporated and/or sublimated source material provided by source elements held by the source arrangement according to the present invention can thereby be provided.

According to another enhanced embodiment of the source arrangement according to the present invention, the actuator is constructed for rotating the holding structure around an axis normal to the center of the holding polygon. As mentioned above, rotating the holding structure by the polygon angle merges the holding polygon back into itself. Hence, by simply rotating the holding structure by the polygon angle, the holding space, and hence especially any source element arranged in the respective holding spaces, assigned to a respective laser beam can be changed, in particular without losing the match between holding spaces and laser beams in both, the first holding position and the second holding position, respectively. Changing the source element and hence the source material actually used for evaporation and/or sublimation can thereby be provided easily.

The source arrangement according to the present invention can also be enhanced further by that the interplanar distance is selected with respect to the incidence angle and the source distance and a plane rotation angle between the relative rotational positions of the holding structure in its first holding position and in its second holding position. By the possibility of a rotation of the holding structure, an additional degree of freedom is introduced in the selection of the variables of a movement of the holding structure. As the source distance between the holding spaces and the incidence angles of the laser beams are fixed, especially due to the arrangement of the holding spaces as regular holding polygon, the rotation angle can especially be used for altering the interplanar distance. In particular, both an enlargement and a reduction of the interplanar distance can be realized, depending on the rotation direction with respect to the direction of the laser beam. A better fitting of the source arrangement according to the present invention into any available space within a TLE system can thereby be provided. Additionally, also available space can be provided for arranging further equipment in the reaction chamber of a TLE system.

According to a second aspect of the invention, the object is satisfied by a thermal laser epitaxy (TLE) system for coating a surface of a substrate with a layer comprising one or more source materials, comprising a reaction chamber enclosing a reaction volume sealable with respect to the ambient atmosphere, a gas system for providing an adjustable reaction atmosphere within the reaction volume, an arrangement means for arranging a substrate within the reaction volume, a substrate heating means for heating the substrate, a laser system for providing one or more laser beams for evaporating and/or sublimating the one or more source materials, and a source arrangement for providing the one or more source materials within the reaction chamber. The TLE system according to the second aspect of the present invention is characterized in that the source arrangement is constructed according to the first aspect of the present invention, and wherein one or more source elements providing the one or more source materials are arranged in the respective holding spaces of the source arrangement.

In the TLE system according to the second aspect of the present invention, a source arrangement according to the first aspect of the present invention is used for arranging the respective source elements. Hence, the TLE system according to the second aspect of the present invention provides the same features and advantages already described above in detail with respect to the source arrangement according to the first aspect of the present invention.

Next to the source arrangement according to the first aspect of the present invention, the TLE system according to the present invention comprises at least the basic elements of TLE systems. A reaction chamber of the TLE system provides a reaction volume sealable with respect to the ambient atmosphere. The intended deposition reaction takes place in said reaction volume. Hence, the source arrangement and also a substrate arranged by suitable arrangement means are placed in the reaction volume.

Further, the reaction volume is fluidly connected to a gas system, which is used for providing an accordingly selected reaction atmosphere in the reaction volume. Said reaction atmosphere can be for instance a vacuum with pressures down to 10⁻¹² hPa or even lower. Alternatively, also a gaseous reaction atmosphere comprising reaction gases suitable for the intended deposition reaction, such as for instance oxygen for a deposition of an oxide.

Substrate heating means, preferably comprising a substrate heating laser, provide a heating of the substrate. For most of the deposition reactions, a substrate heated to a suitable temperature leads to an increase of a quality of the deposited layers, for instance as a mobility of the deposited atoms and/or molecules on the surface of the substrate is increased and hence structural defects within the deposited layer can be healed immediately.

Last but not least, the TLE system according to the present invention also comprises a laser system. The laser system comprises one or more laser sources for producing the one or more laser beams used in the TLE system for evaporation and/or sublimation of the respective source materials. Guidance means and optical elements such as lenses, apertures and/or mirrors are used as elements of the laser system for guiding and forming the laser beam up to the source element with the source material to be evaporated and/or sublimated. If the laser source is arranged outside of the reaction chamber, suitable coupling means, such as for instance a chamber window arranged at a flange of the reaction chamber, are provided in a chamber wall of the reaction chamber for coupling the laser beam into the reaction volume.

By using the source arrangement according to the first aspect of the present invention, source elements providing the source materials can be arranged at the holding spaces of the holding structure of the source arrangement. As the holding structure can be moved by the actuator of the source arrangement between at least the first and second holding position, also the source elements arranged in the respective holding spaces are moved with the holding structure, in particular such that in each of the holding positions one of the source elements is arranged at an interaction position of the laser beam. In other words, in a TLE system according to the present invention, the same laser beam can be used for evaporation and/or sublimation of source material provided by a source element at different positions along the laser beam and hence at different working distances to the surface of the substrate.

According to another embodiment of the TLE according to the present invention, the laser source provides the one or more laser beams with an incidence angle selected in the range between >0° and <90°, in particular between 30° and 60°, preferably with an incidence angle of 45°. The incidence angle is the angle between the surface of the respective source element, which in a special embodiment of the source arrangement according to the present invention is identical to the holding plane.

The incidence angle can in general be chosen freely, as long it is not parallel to the surface of the source element, as in this case effectively no evaporation and/or sublimation take place. As the main flux of the evaporated and/or sublimated source material is normal to the surface of the source element, also an incidence angle of 90° is to be avoided, as in this case said main flux is emitted parallel to the impinging laser beam. This is unfavorable on the one hand as this unavoidably leads to a strong undesired and even harmful coating of elements along the beam path of the laser beam, such as lenses, mirrors or coupling means, and on the other hand the substrate cannot be arranged in said direction of the main flux of evaporated and/or sublimated source material and hence the efficiency of the deposition reaction is reduced drastically. It has been found that incidence angles between 30° and 60° are suitable for a wide range of deposition reactions. Especially an incidence angle of 45° allows a very simple design of the source arrangement, as described above.

Further, the TLE system can also be characterized in that the laser source provides all of the one or more laser beams with the same incidence angle. As described above with respect to the source arrangement according to the first aspect of the present invention, the incidence angle of the laser beam defines the relative position of the holding spaces, and hence of the source elements, and their movement between the interaction positions along the laser beam. For instance, in one of the embodiments of the source arrangement, the interplanar distance between the holding plane in the first holding position and the holding plane in the second holding position, and also the source distance between two holding spaces in the holding plane, depends on said incidence angle. Hence, by providing all laser beams with the same incidence angle, the boundary conditions when designing the source arrangement for the specific TLE system can be simplified. In the exemplary embodiment of the source arrangement mentioned in this paragraph, for all pairs of holding spaces usable with the laser beams, respective equal values for the source distances and also for the interplanar distances can be selected.

In addition, the TLE system according to the present invention can be enhanced further by that the holding structure of the source arrangement comprises three or more holding spaces, wherein the three or more holding spaces form a regular holding polygon, and wherein the laser source provides the one or more laser beams aligned with the sides of the holding polygon. In this embodiment, not only the incidence angles of all laser beams are the same, but also the source distances between the holding space pairs of holding spaces, namely the vertices of the holding polygon. Consequently, also the interplanar distance can be selected equal for all holding space pairs. Moving the holding structure forming the holding polygon from its first holding position to its second holding position changes for all laser beams the active interaction position from the first interaction position to the second interaction position. Changing a composition of the evaporated and/or sublimated source materials can thereby be provided fast and easily. In addition, by aligning the laser beams with the sides of the holding polygon, an interference of the laser beams, also of the reflected laser beams after impinging on the source elements, with elements of the source arrangement or the substrate can be avoided.

According to another enhanced embodiment of the TLE system according to the present invention, the TLE system comprises one or more sensor devices for monitoring the one or more source elements, wherein a central axis of a field of view of the one or more sensor devices is aligned such that it intersects with one of the holding spaces when the holding structure is both in its first holding position and in its second holding position, respectively. In other words, for monitoring two different evaporation and/or sublimation processes, one with the holding structure in its first holding position and one with the holding structure in its second position, only a single sensor device is needed. Hence, the number of needed sensor devices for monitoring all possible evaporation and/or sublimation processes can be drastically reduced, in particular cut in half. The setup of the TLE system according to the present invention can therefore be simplified.

The TLE system according to the present invention can be enhanced further by that the sensor device is a camera and/or a pyrometer. A camera can be used for identifying three-dimensional surface structures present on the source elements during the evaporation and/or sublimation process. Thereby information can be generated, whether the evaporation and/or sublimation process is carried out within the desired parameters. In addition, a brightness of the camera image of the glowing source, in particular when calibrated with the accurate f-stop and exposure time values, provides an indication of the source temperature. A pyrometer is used for more precisely measuring a temperature of the respective source element. Also, this information can be used for monitoring the respective source elements during the evaporation and/or sublimation process.

According to another embodiment, the TLE system according to the present invention can be enhanced further by that the laser beam and the central axis of the sensor device directed to the same holding space when the holding structure is in its first holding position are aligned with respect to each other such that, when the holding structure is in its second holding position, the laser beam intersects a different holding space than the central axis of the sensor device. In other words, the laser beam and the central axis of the sensor device intersect at the respective holding space when the holding structure is in its first holding position, but are pointed differently such that they are directed to different holding spaces when the holding structure is in its second holding position. An interference of the laser beam, also of the reflected laser beam after impinging on the respective source elements, and the sensor device can thereby be avoided.

The invention will be explained in detail in the following by means of embodiments and with reference to the drawings. In particular, in the figures are shown:

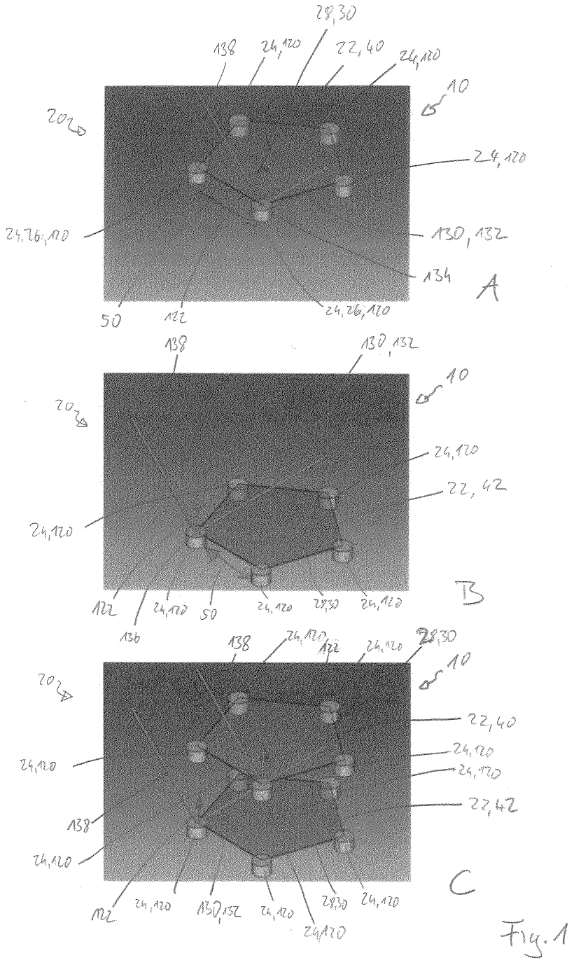

FIG. 1A source arrangement according to the present invention in three schematic views,

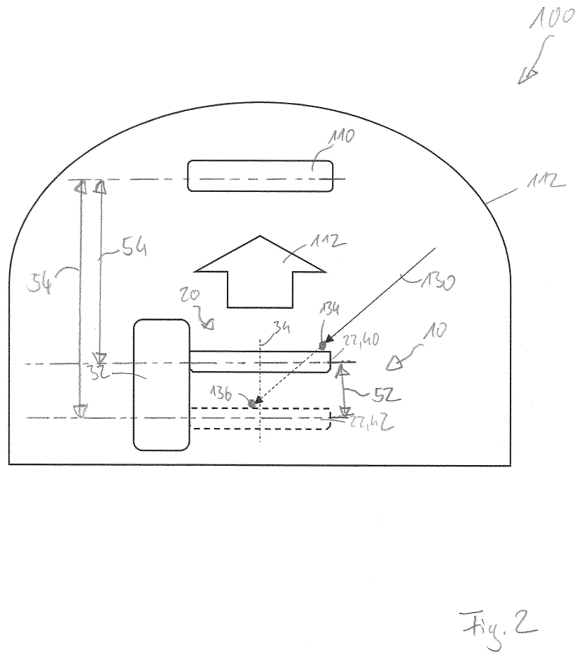

FIG. 2A TLE system according to the present invention in a schematic view,

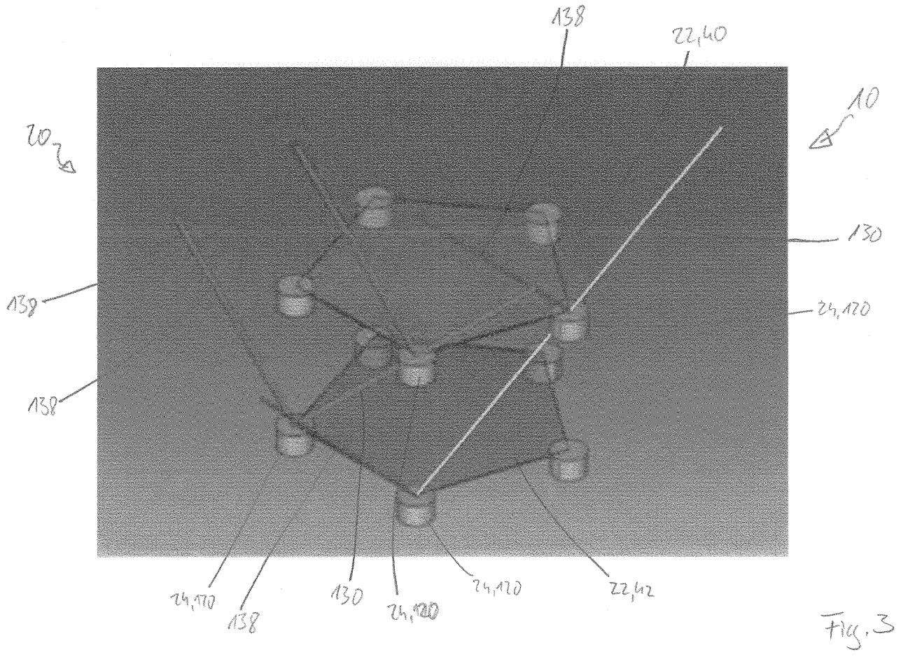

FIG. 3A schematic view of a source arrangement with two laser beams,

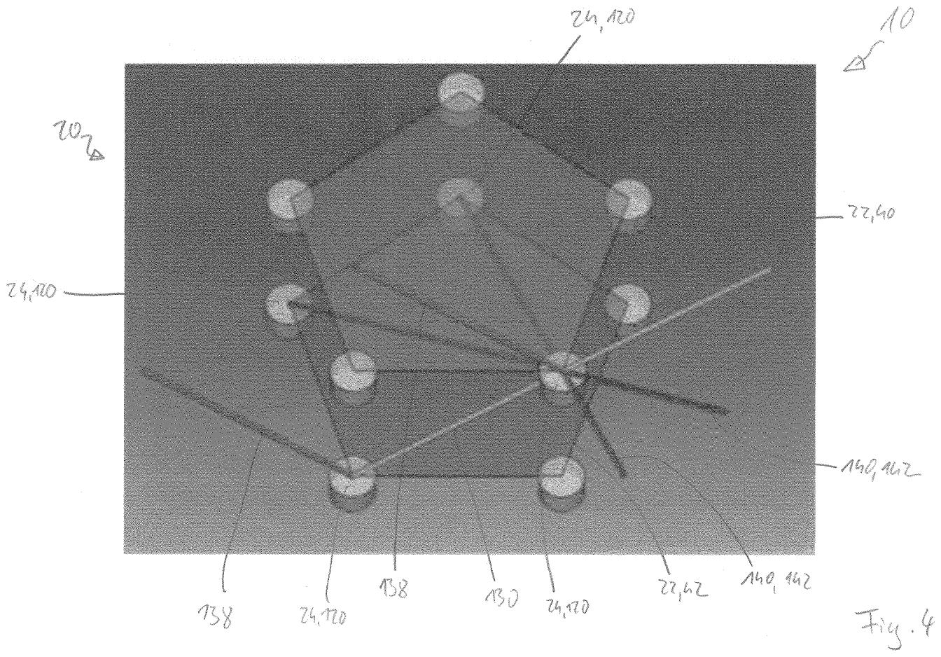

FIG. 4A schematic view of a source arrangement with a laser beam and central axes of possible sensor devices,

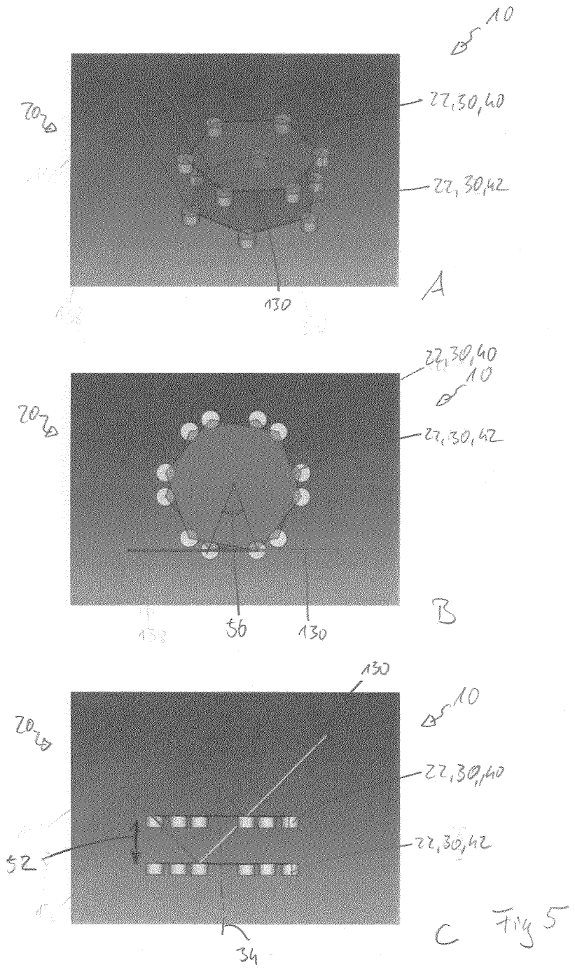

FIG. 5 Another possible embodiment of a source arrangement in three schematic views, and

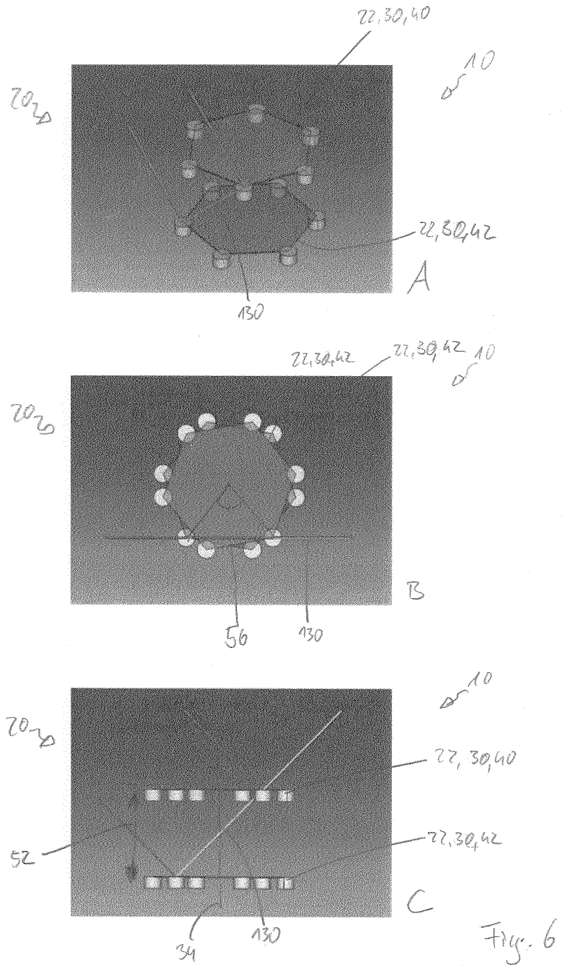

FIG. 6 Yet another possible embodiment of a source arrangement in three schematic views.

FIG. 1 shows a possible embodiment of a source arrangement 10 according to the present invention in three schematic views, wherein subfigure A depicts the holding structure 22 of the source arrangement 10 in its first holding position 40 and a laser beam 130, subfigure B depicts the same holding structure 22, now in its second holding position 42, and also the same laser beam 130, and subfigure C depicts an overlay of subfigure A and B.

The source arrangement 10 depicted in FIG. 1 comprises a holding device 20 with a holding structure 22 comprising five holding spaces 24. In all of the holding spaces 24 a source element 120 of the TLE system 100 (see FIG. 2) is arranged. One of the source elements 120 is illuminated by a laser beam 130 of the TLE system 100 for an evaporation and/or sublimation of the source material provided by the respective source element 120. A mean direction 122 of the evaporated and/or sublimated source material is indicated by an arrow and is generally normal to a surface of the source element 120.

The five holding spaces 24 are arranged in a holding plane 28 and form a regular holding polygon 30. In other words, a source distance 50 (see subfigures A, B) between a holding space pair 26 of holding spaces 24 forming the holding polygon 30 is equal for all holding space pairs 26. For better visuality, only one respective holding space pair 26 is marked in subfigures A, B.

In subfigure A, the holding structure 22 is arranged in its first holding position 40. The laser beam 130 impinges at a first interaction position 134 onto a specific source element 120 arranged in one of the holding spaces 24 and evaporates and/or sublimates the respective source material. The laser beam 130 impinges onto the surfaces of the respective source elements 120 with an incidence angle 132 of 45°.

In contrast to that, in subfigure B, the holding structure 22 is arranged in its second holding position 42. For moving the holding structure 22, the source arrangement 10 comprises an actuator 32 (see FIG. 2) mechanically coupled to the holding structure 22. In the embodiment of the source arrangement 10 according to the present invention depicted in FIG. 1, the actuator 32 linearly moves the holding structure 22 between its first and second holding positions 40, 42.

With the holding structure 22 in its second holding position 42, the same laser beam 130 now impinges onto another source element 120 arranged at another holding space 24 at a second interaction position 136. In other words, by using the source arrangement 10 according to the present invention in a TLE system 100, the same laser beam 130 can be used for evaporation and/or sublimation of source material provided by a source element 120 at different positions within the reaction chamber 112, in particular in different substrate distances 54 (see FIG. 2) to the surface of the substrate 110.

Finally, subfigure C depicts an overlay of the situations shown in subfigure A and B. As is clearly visible, the same laser beam 130 is used for evaporating and/or sublimating source material, independent whether the holding structure 22 is positioned in its first holding position 40 or in its second holding position 42. In addition, it is also visible that not only the path of the incoming laser beams 130, but also a path of the reflected laser beams 138, is unobstructed by any element of the source arrangement 10 according to the present invention.

In FIG. 2, a very schematic side view of a TLE system 100 according to the present invention is shown. In a reaction chamber 112 of the TLE system 100, a source arrangement 10 according to the present invention and a substrate 110 are arranged. For the source arrangement 10, the holding structure 22 of a holding device 20 is depicted in its first holding position 40 (solid line) and in its second holding position 42 (dashed line). The holding structure 22 in its first holding position 40 and in its second holding position 42 are distanced by an interplanar distance 52. This leads to different substrate distances 54 between the substrate 110 and the holding structure in its respective holding positions 40, 42. Further, a laser beam 130 is depicted, up to its first interaction position 134 as solid line, afterwards and up to its second interaction position 136 as dashed line. A linear movement between said holding positions 40, 42 of the holding structure 22 is provided by an actuator 32, which is mechanically coupled to the holding structure 22 of the holding device 20. Additionally, said actuator 32 can also provide a rotational motion of the holding structure 22 around an axis 34. Preferably, the axis 34, and likewise a direction of the linear movement of the holding structure 22 provided by the actuator 32, is aligned parallel to the mean direction 122 of source material evaporated and/or sublimated from the respective source elements 120 (not depicted in FIG. 2, see for instance FIG. 1)

FIG. 3 depicts a source arrangement 10 in a representation similar to subfigure C of FIG. 1. Hence, for details of the source arrangement 10 it is referred to the according description above. However, in contrast to FIG. 1, in FIG. 3 two laser beams 130 are depicted, each of them impinging on different source elements 120, both with the holding structure 22 in its first holding position 40 and in its second holding position 42, respectively. By this, two source materials can simultaneously be evaporated and/or sublimated for providing a combination of said evaporated and/or sublimated source materials as base materials for the coating of the substrate 110 (see FIG. 2).

However, by using the source arrangement 10 according to the present invention, the actually used source elements 120 for evaporation and/or sublimation can be changed easily and in particular quickly and simply, by moving the holding structure from its first holding position 40 into its second holding position 42, and vice versa. Providing a layer structure for the coating of the substrate 110 with different materials for each of the layers can thereby be provided.

Also FIG. 4 depicts a source arrangement 10 in a representation similar to subfigure C of FIG. 1. Hence, for details of the source arrangement 10 it is again referred to the according description above. However, in addition to the content of FIG. 1, in FIG. 4 also two possible central axis 142 of sensor devices 140 (represented also by the line depicting the respective central axes 142) are shown. Said sensor devices 140 can be for instance cameras and/or pyrometers. Preferably, the laser beam 130 and the central axis 142 of the respective sensor device 140 can be directed to the same holding space 24 when the holding structure 22 is in its first holding position 40. Monitoring the evaporation and/or sublimation of the respective source element 120 is thereby possible. However, the laser beam 130 and the central axis 142 are aligned with respect to each other such that, when the holding structure 22 is in its second holding position 42, the laser beam 130 intersects a different holding space 24 than the central axis 142 of the sensor device 140. Harmful interference between the laser beam 130 and the sensor device 140 can thereby be avoided. Is it noted that no central axis 142 of a sensor device 140 is aligned along a side of the holding polygon 30, as an interference with an impinging laser beam 130 (not depicted in FIG. 4) cannot be avoided, or at least cannot be excluded.

As already mentioned above, the actuator 32 (see FIG. 2) can be mechanically coupled to the holding structure 22 such that a rotation of the holding structure 22 can be provided. This allows for instance changing the used source element 120 without moving the holding structure 22 between its holding positions 40, 42.

However, FIGS. 5, 6 show another effect made available by said rotation. In both, FIGS. 5, 6, a holding structure 22 with six holding spaces 24 (only partly marked with reference signs for better visuality) arranged in a regular holding polygon 30 are depicted. In the respective FIG. 5, 6, subfigure A shows an isometric view, subfigure B a top view, and subfigure C a side view, in each case of the respective holding structure 22 in both holding positions 40, 42, together with a laser beam 130.

In contrast to FIG. 1, in which the holding structure 22 is only linearly moved between its holding positions 40, 42, in FIG. 5 said linear movement is superimposed by an additional rotation with a plane rotation angle 56 of 40° (see subfigure B of FIG. 5). Also, in FIG. 6 said superimposed movements are present, but now the plane rotation angle 56 is 80° (see subfigure B of FIG. 6). The respective axis 34 (see the respective subfigure C) is in both cases located at and normal to the center of the holding polygon 30. In both cases, this rotation allows to use the same holding space 24, and hence the same source element 120, independent of the actual holding position 40, 42 of the holding structure 22.

By comparing both subfigures C, the effect of the superimposed rotation is clearly visible. An interplanar distance 54 between the holding structure 22 in its respective holding positions 40, 42 is different for the respective plane rotation angles 56. In summary, by accordingly selecting the plane rotation angle 56, the interplanar distance 52 can be adjusted.

List of references

| | |
|---|---|
| 10 | Source arrangement |
| 20 | Holding device |
| 22 | Holding structure |
| 24 | Holding space |
| 26 | Holding space pair |
| 28 | Holding plane |
| 30 | Holding polygon |
| 32 | Actuator |
| 34 | Axis |
| 40 | First holding position |
| 42 | Second holding position |
| 50 | Source distance |
| 52 | Interplanar distance |
| 54 | Substrate distance |
| 56 | Plane rotation angle |
| 100 | TLE system |
| 110 | Substrate |
| 112 | Reaction chamber |
| 120 | Source element |
| 122 | Mean direction |
| 130 | Laser beam |
| 132 | Incidence angle |
| 134 | First interaction position |
| 136 | Second interaction position |
| 138 | Reflected laser beam |
| 140 | Sensor device |
| 142 | Central axis |

1-25. (canceled)

26. Source arrangement for a thermal laser epitaxy (TLE) system, comprising a holding device with a movable holding structure with one or more holding spaces for the arrangement of one or more source elements providing a source material to be evaporated and/or sublimated by a laser beam of the TLE system for a coating of a substrate of the TLE system, further comprising an actuator mechanically coupled to the holding structure, whereby the actuator is constructed to move the holding structure between two or more holding positions, wherein in a first holding position of the two or more holding positions one of the one or more source elements arranged in the respective holding spaces is positional along the laser beam at a first interaction position, and wherein in a second holding position of the two or more holding positions one of the one or more source elements arranged in the respective holding spaces is positional along the laser beam at a second interaction position different to the first interaction position.

27. Source arrangement according to claim 26,
wherein in a mounted state of the source arrangement, a substrate distance of the second holding position to the substrate is larger than a substrate distance of the first holding position to the substrate.

28. Source arrangement according to claim 26,
wherein the second interaction position is downstream on the laser beam with respect to the first interaction position.

29. Source arrangement according to claim 26,
wherein the actuator is constructed for linearly moving the holding structure and/or for rotating the holding structure.

30. Source arrangement according to claim 29,
wherein the linear movement of the holding structure is parallel to a mean direction of the evaporated and/or sublimated source material of the respective source element when illuminated by the laser beam.

31. Source arrangement according to claim 29,
wherein an axis of the rotational movement of the holding structure is parallel to the mean direction of the evaporated and/or sublimated source material of the respective source element arranged in the respective holding space when illuminated by the laser beam.

32. Source arrangement according to claim 26,
wherein a first holding space arrangeable at the first interaction position along the laser beam when the holding structure is in its first holding position is the same as a second holding space arrangeable at the second interaction position along the laser beam when the holding structure is in its second holding position.

33. Source arrangement according to claim 26,
wherein a first holding space arrangeable at the first interaction position along the laser beam when the holding structure is in its first holding position is different from a second holding space arrangeable at the second interaction position along the laser beam when the holding structure is in its second holding position.

34. Source arrangement according to claim 33,
wherein the first holding space and the second holding space are arranged at the holding structure in a holding plane, wherein the holding plane is normal to the mean direction of the evaporated and/or sublimated source material of the respective source element arranged in the respective holding space when illuminated by the laser beam.

35. Source arrangement according to claim 34,
wherein the linear movement of the holding structure provided by the actuator is parallel to the mean direction of the evaporated and/or sublimated source material of the respective source element arranged in the respective holding space when illuminated by the laser beam, and wherein a source distance between the first holding space and the second holding space within the holding plane and an interplanar distance of the holding plane with the first holding space in the first interaction position to the holding plane with the second holding space in the second interaction position are selected with respect to an incidence angle of the laser beam of the TLE system on a surface of the source element arrangeable in the first holding space and the second holding space, respectively.

36. Source arrangement according to claim 35,
wherein the source distance and the interplanar distance are selected such that the value of the interplanar distance divided by the value of the source distance is the tangent of the incidence angle.

37. Source arrangement according to claim 35,
wherein the source arrangement is constructed for usage in a TLE system with at least a first laser beam and a second laser beam and hence comprises at least two holding space pairs of a first holding space and a second holding space, wherein the respective source distance between the first holding space and the second holding space of each holding space pair is selected with respect to the incidence angle of the respective laser beam and a common interplanar distance.

38. Source arrangement according to claim 37,
wherein the respective incidence angles of the respective laser beams and hence the respective source distances of the holding space pairs are different.

39. Source arrangement according to claim 37,
wherein the respective incidence angles of the respective laser beams and hence the respective source distances of the holding space pairs are equal.

40. Source arrangement according to claim 39,
wherein the holding structure comprises three or more holding spaces, wherein the three or more holding spaces form a regular holding polygon.

41. Source arrangement according to claim 40,
wherein a center of the holding polygon is arrangeable in the TLE system opposite to the substrate.

42. Source arrangement according to claim 40,
wherein the actuator is constructed for rotating the holding structure around an axis normal to the center of the holding polygon.

43. Source arrangement according to claim 42,
wherein the interplanar distance is selected with respect to the incidence angle and the source distance and a plane rotation angle between the relative rotational positions of the holding structure in its first holding position and in its second holding position.

44. Thermal laser epitaxy (TLE) system for coating a surface of a substrate with a layer comprising one or more source materials, comprising a reaction chamber enclosing a reaction volume sealable with respect to the ambient atmosphere, a gas system for providing an adjustable reaction atmosphere within the reaction volume, an arrangement means for arranging a substrate within the reaction volume, a substrate heating means for heating the substrate, a laser system for providing one or more laser beams for evaporating and/or sublimating the one or more source materials, and a source arrangement for providing the one or more source materials within the reaction chamber, wherein the source arrangement comprises a holding device with a movable holding structure with one or more holding spaces for the arrangement of one or more source elements providing a source material to be evaporated and/or sublimated by a laser beam of the TLE system for a coating of a substrate of the TLE system, further comprises an actuator mechanically coupled to the holding structure, whereby the actuator is constructed to move the holding structure between two or more holding positions, wherein in a first holding position of the two or more holding positions one of the one or more source elements arranged in the respective holding spaces is positional along the laser beam at a first interaction position, and wherein in a second holding position of the two or more holding positions one of the one or more source elements arranged in the respective holding spaces is positional along the laser beam at a second interaction position different to the first interaction position, and wherein one or more source elements providing the one or more source materials are arranged in the respective holding spaces of the source arrangement.

45. TLE system according to claim 44,
wherein the laser source provides the one or more laser beams with an incidence angle selected in the range between >0° and <90°.

46. TLE system according to claim 44,
wherein the laser source provides all of the one or more laser beams with the same incidence angle.

47. TLE system according to claim 46,
wherein the holding structure of the source arrangement comprises three or more holding spaces, wherein the three or more holding spaces form a regular holding polygon, and wherein the laser source provides the one or more laser beams aligned with the sides of the holding polygon.

48. TLE system according to claim 47,
wherein the TLE system comprises one or more sensor devices for monitoring the one or more source elements, wherein a central axis of a field of view of the one or more sensor devices is aligned such that it intersects with one of the holding spaces when the holding structure is both in its first holding position and in its second holding position, respectively.

49. TLE system according to claim 48,
wherein the sensor device is a camera and/or a pyrometer.

50. TLE system according to claim 48,
wherein the laser beam and the central axis of the sensor device directed to the same holding space when the holding structure is in its first holding position are aligned with respect to each other such that, when the holding structure is in its second holding position, the laser beam intersects a different holding space than the central axis of the sensor device.

51. TLE system according to claim 44,
wherein the laser source provides the one or more laser beams with an incidence angle selected in the range between 30° and 60°.

52. TLE system according to claim 44,
wherein the laser source provides the one or more laser beams with an incidence angle of 45°.
